(19) United States
(12) Patent Application Publication
(10) Pub. No.: US 2025/0373079 A1
(43) Pub. Date: Dec. 4, 2025

(54) MAGNETIC THERMOELECTRIC COOLING ASSEMBLY AND MAGNETIC WIRELESS CHARGER WITH COOLING FUNCTIONALITY

(71) Applicant: Shenzhen Chenxing Electrical Appliances Co., Ltd., Shenzhen (CN)

(72) Inventor: Xianzhou SHEN, Chibi (CN)

(73) Assignee: Shenzhen Chenxing Electrical Appliances Co., Ltd., Shenzhen (CN)

(21) Appl. No.: 19/212,136

(22) Filed: May 19, 2025

(30) Foreign Application Priority Data
May 29, 2024 (CN) 202421196044.1
May 29, 2024 (CN) 202421196048.X
May 29, 2024 (CN) 202421205101.8

(51) Int. Cl. H02J 50/10; H02J 50/00; H02J 50/90; H05K 7/20; H10N 10/80

(52) U.S. Cl. CPC H02J 50/10; H02J 50/005; H02J 50/90; H05K 7/20163; H05K 7/2029; H05K 7/20409; H05K 7/20454; H10N 10/80

(57) ABSTRACT

Disclosed are a magnetic thermoelectric cooling assembly and a magnetic wireless charger with cooling functionality. The cooling assembly includes a thermoelectric cooling chip, which includes a concave cavity for accommodating a charging coil and a magnet. This allows the cooling effect to act directly on the mobile terminal without requiring conduction through the charging coil and magnet, significantly improving cooling performance. The magnetic wireless charger with cooling functionality, by utilizing the magnetic thermoelectric cooling assembly, achieves excellent cooling effects and is highly portable.

### CROSS-REFERENCE TO RELATED APPLICATIONS

This application claims priority to Chinese Patent Application No. 202421196048.X, filed on May 29, 2024; Chinese Patent Application No. 202421196044.1, filed on May 29, 2024; and Chinese Patent Application No. 202421205101.8, filed on May 29, 2024. The disclosures of the above-mentioned applications are hereby incorporated by reference in their entireties.

### TECHNICAL FIELD

The present disclosure relates to the technical field of wireless charging devices, specifically to a magnetic thermoelectric cooling assembly and a magnetic wireless charger with cooling functionality.

### BACKGROUND

With the increasing demand for fast charging technology among mobile terminal users, manufacturers have intensified research in this area. As research progresses, it has been found that while charging power increases, the heat generated at the contact point between the mobile terminal and the wireless charging device becomes particularly severe. When the temperature reaches a certain threshold, the charging power cannot be further increased, failing to achieve the desired effect, thus necessitating cooling solutions.

Thermoelectric cooling chips are widely used for cooling components due to their compact size and rapid cooling capabilities.

Chinese Patent Publication CN218352234U discloses a cooling device for a vehicle-mounted wireless charging base, comprising a thermoelectric cooling chip and a control unit. The thermoelectric cooling chip is installed on the vehicle-mounted wireless charging base, and during operation of the wireless charging base, the control unit is used to regulate the thermoelectric cooling chip to dissipate heat from the charging base. By providing the thermoelectric cooling chip, this solution actively transfers heat accumulated in the vehicle-mounted wireless charging area during charging and then dissipates it, keeping the cooling fan away from the charging base to ensure heat dissipation while avoiding noise pollution.

However, whether it is an in-car wireless charging dock, a desktop wireless charging dock, or a portable power bank, charging coils and magnets are required. In the cooling devices of the above structures, the charging coil and magnet can only be placed on top of the semiconductor cooling plate, meaning the cold energy generated by the semiconductor cooling plate must pass through the charging coil and magnet before being transferred to the mobile terminal. This process results in significant loss of cold energy, leading to poor cooling performance.

Therefore, it is necessary to design a new cooling component to address the issue of poor cooling performance.

Chinese Patent Publication CN220553839U discloses a wireless charging heat dissipation device and a wireless charger. The wireless charging heat dissipation device includes a transmitter module, a heat dissipation component, and a metal casing. The metal casing is connected to the heat dissipation side of the heat dissipation component, and the metal casing has an annular placement surface that faces away from the heat dissipation component and is used to place the mobile terminal. The transmitter module is located within the charging space enclosed by the annular placement surface and forms an electrical coupling with the receiving module of the mobile terminal. The metal casing has high thermal conductivity, enabling rapid heat conduction. The annular placement surface of the metal casing contacts the mobile terminal, thereby transferring the heat from the mobile terminal to the heat dissipation component via the metal casing, which then cools it down. This configuration effectively enhances the heat dissipation performance of the wireless charging device, allowing the mobile terminal to maintain a low temperature and sustain high charging power. While this solution can cool the mobile terminal to some extent by incorporating the heat dissipation component and metal casing, the cooling effect is not significant. This is because the cooling plate in this solution is in contact with the transmitter module, which includes a transmitter coil and magnet. Installing the transmitter coil and magnet requires a substrate, the cold energy generated by the cooling plate must first pass through the substrate, where it is absorbed by the substrate, transmitter coil, and magnet. The remaining cold energy is then transferred to the mobile terminal via the substrate, transmitter coil, and magnet. Since the transmitter coil also generates heat during operation, the actual cold energy transferred to the mobile terminal is minimal, resulting in poor cooling performance. Additionally, the transmitter module, metal casing, heat dissipation component, and fan in this structure are all stacked in the thickness direction, making the charger bulky and unsuitable for portable use. Therefore, it is necessary to design a new charger to address the above issues.

### SUMMARY

The present disclosure aims to resolve the technical issues of poor cooling performance in existing cooling devices and chargers, as well as the large size of chargers, which makes them inconvenient to carry.

To achieve the above object, the technical solution of the present disclosure is as follows.

A magnetic thermoelectric cooling assembly comprises a thermoelectric cooling chip, which comprises a cooling surface and a heating surface, wherein the thermoelectric cooling chip has a concave cavity extending from a side of the cooling surface toward a side of the heating surface, with the cooling surface forming a cavity base cooling surface and a cavity top cooling surface with a height difference; and on the side of the heating surface, a heat dissipation device is provided, and the heat dissipation device comprises a thermal conduction component of a certain length, with one end of the thermal conduction component contacting the heating surface for heat transfer; the other end of the heat dissipation device is equipped with a heat dissipation component to increase a heat dissipation area or a heat storage capacity; and a magnetic component is arranged within the concave cavity.

With the above configuration, the concave cavity can accommodate components such as a charging coil and a magnet. The cooling capacity generated by the cavity base cooling surface can cool the charging coil and magnet, keeping the charging coil at a lower temperature. Meanwhile, the thermoelectric cooling chip, charging coil, and magnet can be arranged nearly on the same plane. Thus, the cooling capacity produced by the cavity top cooling surface can directly act on the mobile terminal without conduction through the charging coil and magnet, significantly improving cooling efficiency. Additionally, the thermal conduction component promptly transfers heat from the heating surface to the heat dissipation component, which dissipates the heat. The thermoelectric cooling chip, thermal conduction component, and heat dissipation component do not need to be stacked vertically, effectively reducing the overall thickness of the cooling assembly. The magnetic component in the concave cavity enables magnetic adsorption of the mobile terminal, enhancing charging convenience for the mobile terminal.

A magnetic thermoelectric cooling assembly comprises a ring-shaped thermoelectric cooling chip, which comprises a cooling surface and a heating surface, wherein a heat dissipation device is provided on a side of the heating surface; and the heat dissipation device comprising a thermal conduction component of a certain length, and the thermal conduction component is in contact with the heating surface for heat transfer; and one end of the thermal conduction component forms a ring matching a shape of the ring-shaped thermoelectric cooling chip, and at the other end of the thermal conduction component, a heat dissipation component is provided to increase a heat dissipation area or a heat storage capacity; and a magnetic component is provided on an inner or outer ring of the ring-shaped thermoelectric cooling chip.

With the above configuration, the structural features of the ring-shaped thermoelectric cooling chip create an internal space for accommodating the charging coil and magnet. The ring-shaped thermoelectric cooling chip, charging coil, and magnet can be arranged largely on the same plane. As a result, the cooling generated by the cooling surface can be directly conducted away without needing to pass through the charging coil and magnet, significantly improving the cooling effect. Meanwhile, the thermal conduction component can promptly transfer the heat generated by the heating surface to the heat dissipation component, which then dissipates the heat, further enhancing the cooling efficiency of the ring-shaped thermoelectric cooling chip. Additionally, the thermoelectric cooling chip, thermal conduction component, and heat dissipation component do not need to be stacked in the height direction, effectively reducing the overall thickness of the cooling assembly. Placing magnetic components on the inner or outer ring of the ring-shaped thermoelectric cooling chip enables magnetic adsorption of the mobile terminal, improving the convenience of charging the mobile terminal.

A magnetic wireless charger with cooling functionality comprises a housing, inside which a thermoelectric cooling assembly and a control assembly are arranged, wherein the thermoelectric cooling assembly comprises a thermoelectric cooling chip, which comprises a cooling surface and a heating surface; wherein the cooling surface protrudes from the housing or contacts the housing to transfer cold through the housing; a heat dissipation device is provided on a side of the heating surface, and the heat dissipation device comprises a thermal conduction component with a certain length, one end of which contacts the heating surface for heat transfer; at the other end of the thermal conduction component, a heat dissipation component is provided to increase a heat dissipation area or a heat storage capacity; and the thermoelectric cooling assembly further comprises a magnetic component and a coil, which are embedded in the thermoelectric cooling chip.

With the above structure, the cooling surface of the thermoelectric cooling chip extends out of the housing or directly contacts it, allowing the cooling surface to directly touch the mobile terminal or connect via a metal casing with high cooling efficiency. In both cases, the cooling transfer is direct, with minimal loss and excellent cooling performance. The magnet and coil embedded in the thermoelectric cooling chip do not obstruct contact between the cooling surface and the mobile terminal. The heat generated by the heating surface is first conducted through the thermal conduction component to the heat dissipation component, which then dissipates it. Since the heat dissipation component and thermoelectric cooling chip are not stacked in the thickness direction, the overall thickness can be effectively reduced, enabling the charger to be made very thin for easy portability.

### BRIEF DESCRIPTION OF THE DRAWINGS

FIG. 1 is a schematic diagram of the overall structure of Embodiment 1 of the present disclosure.

FIG. 2 is an exploded view of Embodiment 1 of the present disclosure.

FIG. 3 is a cross-sectional view of the thermoelectric cooling chip in Embodiment 1 of the present disclosure.

FIG. 4 is a schematic diagram of the overall structure of Embodiment 2 of the present disclosure.

FIG. 5 is an exploded view of Embodiment 2 of the present disclosure.

FIG. 6 is a schematic diagram of another structure of the thermoelectric cooling chip in the embodiment of the present disclosure.

FIG. 7 is a schematic diagram of the thermoelectric cooling chip as a split structure in the embodiment of the present disclosure.

FIG. 8 is a perspective view of the split-structure thermoelectric cooling chip in the embodiment of the present disclosure.

FIG. 9 is a schematic diagram of the overall structure in Embodiment 3 of the present disclosure.

FIG. 10 is an exploded view of Embodiment 3 of the present disclosure.

FIG. 11 is a schematic diagram of another implementation of the heat dissipation component in Embodiment 3 of the present disclosure.

FIG. 12 is an exploded view of Embodiment 4 of the present disclosure.

FIG. 13 is a schematic diagram of the structure in Embodiment 5 of the present disclosure.

FIG. 14 is a schematic diagram of the structure after removing the rear housing in Embodiment 5 of the present disclosure.

FIG. 15 is an exploded view of Embodiment 5 of the present disclosure.

FIG. 16 is a schematic diagram of the structure in Embodiment 7 of the present disclosure.

FIG. 17 is an exploded view of Embodiment 7 of the present disclosure.

FIG. 18 is a schematic diagram of the structure in Embodiment 8 of the present disclosure.

FIG. 19 is an exploded view of Embodiment 8 of the present disclosure.

FIG. 20 is a schematic diagram of the structure in Embodiment 9 of the present disclosure.

FIG. 21 is an exploded view of Embodiment 9 of the present disclosure.

FIG. 22 is a schematic diagram of the structure where the thermoelectric cooling chip directly contacts the housing in the embodiment of the present disclosure.

### DETAILED DESCRIPTION OF THE EMBODIMENTS

The present disclosure is further described in detail below with reference to the accompanying drawings and specific embodiments.

### Embodiment 1

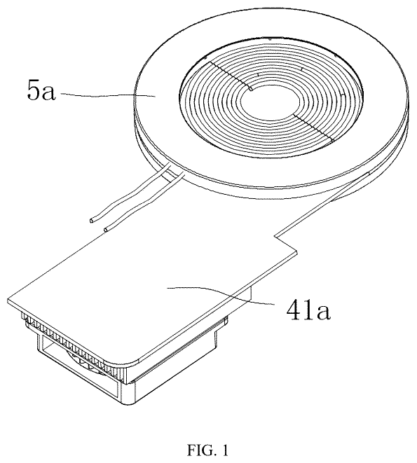

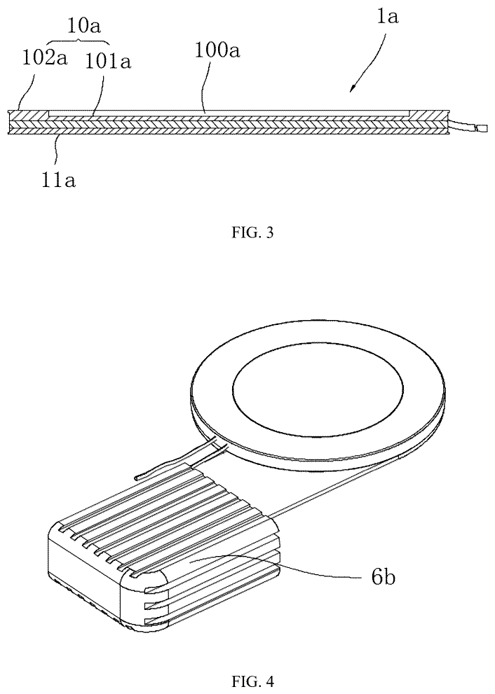

As shown in FIGS. 1 to 3, the magnetic thermoelectric cooling assembly 1003a includes a thermoelectric cooling chip la, which includes a cooling surface 10a and a heating surface 11a. When powered, the temperature of the cooling surface 10a rapidly decreases to achieve cooling, while the heating surface 11a rapidly increases in temperature. The principle of thermoelectric cooling is publicly known prior art and will not be elaborated here.

In this embodiment, the thermoelectric cooling chip 1a has a concave cavity 100a extending from the cooling surface 10a side toward the heating surface 11a side, forming a cavity base cooling surface 101a and a cavity top cooling surface 102a with a height difference.

Thus, the concave cavity 100a can accommodate components such as the charging coil 2a and the magnet 3a. The cold energy generated by the cavity base cooling surface 101a can cool both the charging coil 2a and the magnet 3a, as well as the wireless terminal, keeping the charging coil 2a, magnet 3a, and wireless terminal at a lower temperature. Meanwhile, the thermoelectric cooling chip la, charging coil 2a, and magnet 3a can be arranged substantially on the same plane. The cold energy generated by the cavity top cooling surface 102a can directly act on the mobile terminal without conduction through the charging coil 2a and magnet 3a, significantly improving the cooling effect on the mobile terminal. The aforementioned mobile terminal may be a phone, tablet, or laptop.

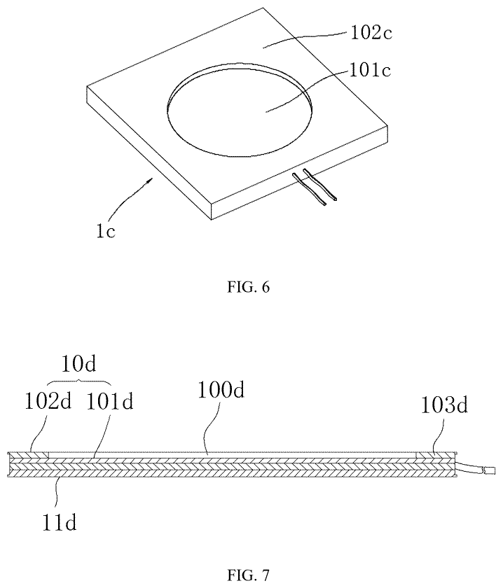

To increase the contact area between the cooling surface and the mobile terminal, as shown in FIG. 6, the thermoelectric cooling chip 1c is shaped into a rectangle, meaning the cavity top cooling surface 102c is rectangular, while the cross-section of the cavity base cooling surface 101c is circular. When the magnetic thermoelectric cooling assembly incorporating this thermoelectric cooling chip is used in a charger or power bank, the cavity top cooling surface 102c can directly contact the mobile terminal, resulting in a larger contact area and better cooling performance.

Typically, the cavity base cooling surface 101a and cavity top cooling surface 102a can be integrally formed by ceramic die-casting or aluminum alloy casting. Of course, they can also be integrally formed from metals with high thermal conductivity, such as copper.

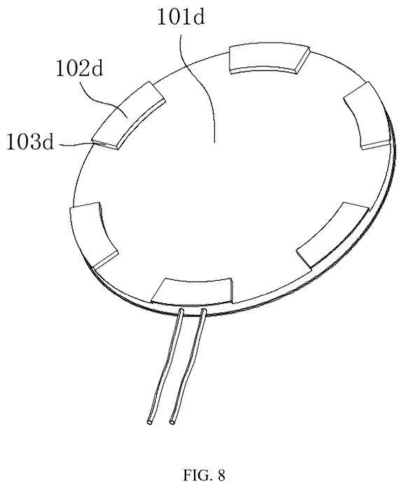

In another embodiment, a flange 103d may also be arranged on the outer side of the cooling surface 10d, as shown in FIGS. 7 and 8. The flange 103d forms the concave cavity 100d on the cooling surface. Since the concave cavity 100d only needs to accommodate the charging coil 2 and magnet 3 and does not require sealing, the flange 103d can be either continuous or discontinuous. In this case, the top surface of the flange 103d serves as the cavity top cooling surface 102d, and the bottom surface of the concave cavity 100d serves as the cavity base cooling surface 101d. The substrate forming the cooling surface 10d can be either a ceramic substrate or a metal substrate. The flange 103d can be made of ceramic or metal and is connected to the cooling surface by welding or adhesive bonding. This solution is another approach to achieve a thermoelectric cooling chip with a height-differentiated cooling surface.

On the side of the heating surface 11a, a heat dissipation device is provided, which includes a thermal conduction component 41a of a certain length. One end of the thermal conduction component 41a contacts the heating surface 11a for heat transfer.

In this embodiment, the thermal conduction component 41a is a Vapor Chamber (VC) liquid-cooled heat spreader. The shape of the end of the VC liquid-cooled heat spreader in contact with the thermoelectric cooling chip 1a matches the shape of the thermoelectric cooling chip 1a.

The VC liquid-cooled heat spreader is also known as a vacuum chamber heat spreader or thermal equalization plate. The English name for VC is Vapor Chamber. The VC liquid-cooled heat spreader is a highly efficient heat transfer component and is a mature existing technology, so its specific structure will not be elaborated here.

To improve heat conduction and heat storage, the heat dissipation device may also include a heat storage unit 42a located at the bottom of the thermal conduction component 41a. One end of the thermal conduction component 41a may also be embedded within the heat storage unit 42a.

As another implementation of the thermal conduction component, it may be a copper tube embedded in the heat storage unit, which can be an aluminum or copper block, serving the same functions of heat conduction and storage.

During assembly, thermal grease is applied between the heating surface 11a and the thermal conduction component 41a to enhance heat transfer efficiency.

In this embodiment, the magnet 3a is placed within the cavity base cooling surface 101a. The magnet 3a can be made into small individual pieces or a complete ring, as long as it can adsorb the mobile terminal.

In this embodiment, a cold conduction component 5a is provided on the side of the cooling surface 10a of the ring-shaped thermoelectric cooling chip 1a, which can simultaneously cover the thermoelectric cooling chip 1a and the magnet 3a.

The cold conduction component 5a can be made of metal or materials such as thermal conductive silicone, and it is used to contact the mobile terminal.

In this embodiment, the cold conduction component 5a is formed by aluminum alloy drawing and stamping. Thermal grease is applied on the surface where the cold conduction component 5a contacts the thermoelectric cooling chip 1a to improve cooling efficiency.

The charging coil 2a is also located within the cavity base cooling surface 101a, and the charging coil 2a is positioned inside the magnet 3a. To shield the charging coil 2a, a non-metallic surface cover is typically installed on the exterior of the charging coil 2a.

At the end of the thermal conduction component 41a away from the thermoelectric cooling chip 1a, a heat dissipation component 6a is provided to increase the heat dissipation area or heat storage capacity.

In this embodiment, the heat dissipation component 6a is a heat dissipation fin array, which is tightly connected to the thermal conduction component 41a to facilitate heat dissipation. To reduce costs, the heat dissipation fin array is usually made of aluminum alloy, though it can also be made of copper alloy.

To enhance the heat dissipation capability of the heat dissipation fin array, a cooling fan 7a is also installed on the heat dissipation fin array. The air intake of the cooling fan 7a is positioned close to the heat dissipation fin array to strengthen air convection and improve cooling efficiency.

### Embodiment 2

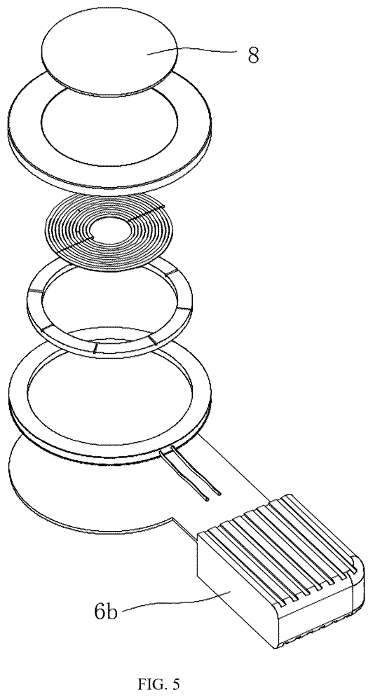

As shown in FIGS. 4 and 5, except for the difference in the heat dissipation component, the rest of the structure is the same as in Embodiment 1. When the cooling power is low, the heat dissipation component can be a heat sink block 6b, with grooves on its surface to increase the heat dissipation area. This approach eliminates the need for a cooling fan for the heat sink block 6b, thereby reducing production costs.

FIG. 5 shows a schematic diagram of the structure of the non-metallic surface cover 8.

With the above configuration, the thermal conduction component 41a can promptly transfer the heat generated by the heating surface 11a to the heat dissipation component 6a or 6b, which then dissipates the heat, thereby maintaining the cooling effect of the thermoelectric cooling chip 1a.

### Embodiment 3

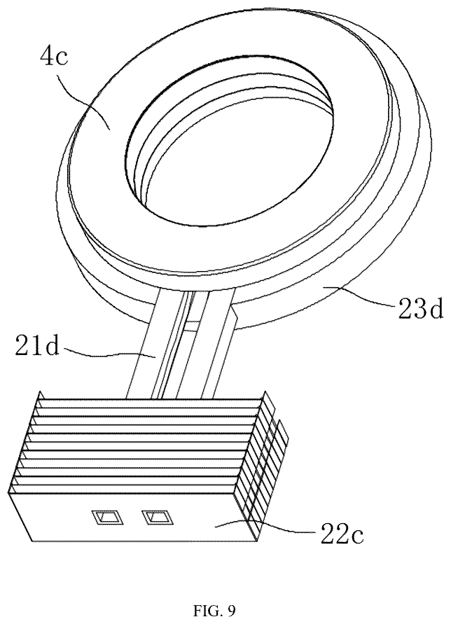

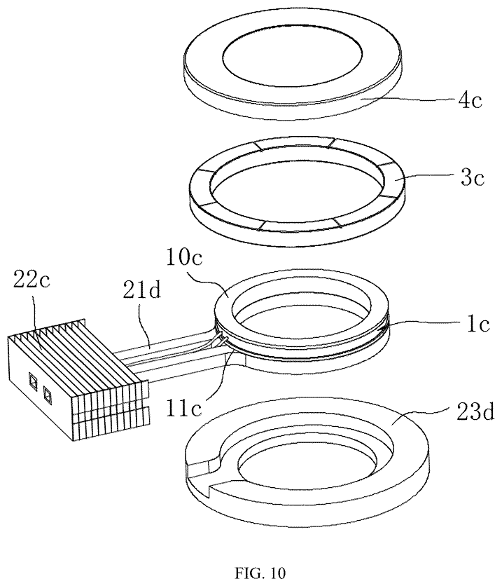

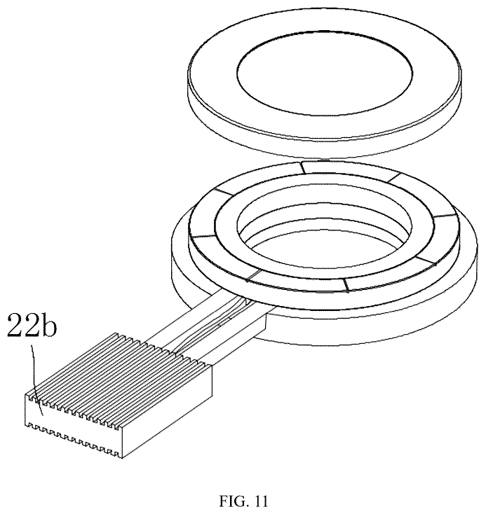

As shown in FIGS. 9 and 10, the magnetic thermoelectric cooling assembly includes a ring-shaped thermoelectric cooling chip 1c.

To simplify the structure, in this embodiment, the cross-section of the ring-shaped thermoelectric cooling chip 1c is designed as a circular ring. Of course, the cross-section of the ring-shaped thermoelectric cooling chip 1c can also be any other required shape, such as rectangular, diamond, or oval. The cross-sectional shape does not affect functionality as long as it meets the requirements. Thus, the center of the ring-shaped thermoelectric cooling chip 1c provides an accommodating space. Since the ring-shaped thermoelectric cooling chip 1c is a mature existing technology, its specific structure is not elaborated here.

The ring-shaped thermoelectric cooling chip 1c has a cooling surface 10c and a heating surface 11c. When powered, the temperature of the cooling surface 10c rapidly decreases to achieve cooling, while the temperature of the heating surface 11c rapidly rises.

A heat dissipation device is provided on the side of the heating surface 11c. The heat dissipation device includes a thermal conduction component 21d with a certain length, which contacts the heating surface 11c for heat transfer. One end of the thermal conduction component 21d forms a ring matching the shape of the ring-shaped thermoelectric cooling chip 1c.

In this embodiment, the thermal conduction component 21d is a copper tube. The middle section of the copper tube is bent to form a ring matching the shape of the ring-shaped thermoelectric cooling chip 1c, while the two ends of the copper tube extend parallelly away from the ring. This configuration simplifies the processing of the copper tube.

At the other end of the thermal conduction component 21d, a heat dissipation component 22c is provided to increase the heat dissipation area or heat storage capacity.

In this embodiment, the heat dissipation component 22c is a heat dissipation fin array, which is tightly connected to the thermal conduction component 21d to facilitate heat dissipation. To reduce costs, the heat dissipation fin array is typically made of aluminum alloy, though it can also be made of copper alloy.

To enhance the heat dissipation efficiency of the heat dissipation fin array, a cooling fan (not shown) is also installed on the fin array. The intake of the cooling fan is positioned close to the fin array to strengthen air convection and improve heat dissipation.

The heat dissipation device also includes a heat storage unit 23d. In this embodiment, the heat storage unit 23d is designed as a ring, with its outer diameter larger than that of the thermal conduction component 21d; the inner diameter of the heat storage unit 23d is less than or equal to the outer diameter of the thermal conduction component 21d.

The ring-shaped end of the thermal conduction component 21d is embedded within the heat storage unit 23d. Typically, when the installation space is sufficient, the top surface of the thermal conduction component 21d is flush with the top surface of the heat storage unit 23d. However, if needed, the top surface of the thermal conduction component 21d can be set lower than that of the heat storage unit 23d, meaning the thermal conduction component 21d is embedded deeper into the heat storage unit 23d, thereby reducing the combined height and making the assembly thinner.

Typically, to reduce costs, the heat storage unit 23d is made of aluminum alloy, though it can also be made of copper alloy.

The heat storage unit 23d not only stores heat but also dissipates some heat due to its heat dissipation area.

As another implementation of this embodiment, the heat storage unit 23d is circular (not shown), with its outer diameter larger than that of the thermal conduction component 21d. A cavity is created on the heat storage unit 23d, extending inward from the side in contact with the thermal conduction component 21d.

In addition to the above implementations, the heat storage unit 23d can also be rectangular (not shown), with through holes or cavities created on the heat storage unit 23d.

A magnetic component is placed on the inner or outer ring of the ring-shaped thermoelectric cooling chip 1c.

In this embodiment, the magnetic component is a magnet 3c, located outside the ring-shaped thermoelectric cooling chip 1c. The magnet 3c can be made as small individual pieces or as a complete ring, as long as it can adsorb the mobile terminal.

On the side of the cooling surface of the ring-shaped thermoelectric cooling chip 1c, a cold conduction component 4c is placed, which simultaneously covers the ring-shaped thermoelectric cooling chip 1c and the magnet 3c.

The cold conduction component 4c can be made of metal or thermal conductive silicone. The cold conduction component 4c is used to contact the mobile terminal. In this embodiment, the cold conduction component 4c is formed by drawing and stamping aluminum alloy.

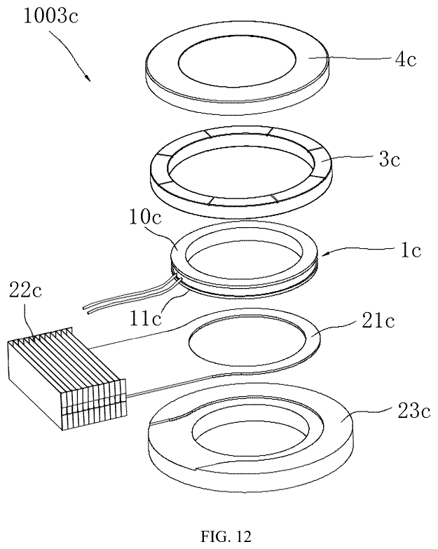

As shown in FIG. 11, as an alternative implementation, when the cooling power is low, the heat dissipation component can be a heat sink block 22b, with grooves on its surface to increase the heat dissipation area. This approach eliminates the need for a cooling fan for the heat sink block 22b, thereby reducing production costs.

### Embodiment 4

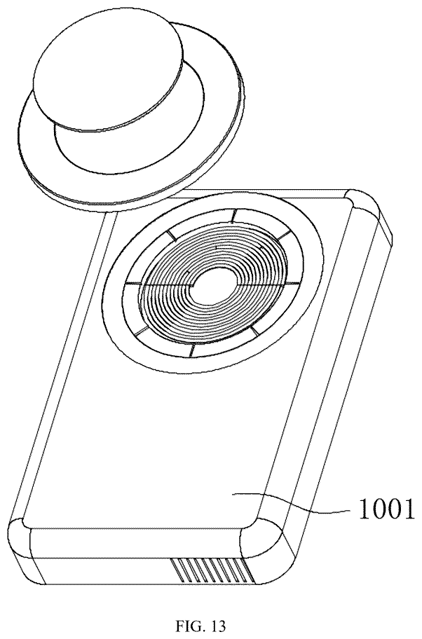

As shown in FIG. 12, the difference from Embodiment 3 lies in that the thermal conduction component is a VC liquid-cooled heat spreader 21c. The end of the VC liquid-cooled heat spreader 21c in contact with the ring-shaped thermoelectric cooling chip 1c forms a ring matching the shape of the ring-shaped thermoelectric cooling chip 1c.

During assembly, thermal grease is applied between the cooling surface 10c and the cold conduction component 4c, as well as between the heating surface 11c and the thermal conduction component, to enhance the efficiency of cold and heat conduction.

In this solution, the structural features of the ring-shaped thermoelectric cooling chip 1c create internal space for accommodating the charging coil and magnet. The ring-shaped thermoelectric cooling chip 1c, charging coil, and magnet 3c can be arranged largely on the same plane. Thus, the cold generated by the cooling surface 10c can be directly conducted away without passing through the charging coil and magnet 3c, significantly improving cooling efficiency. Meanwhile, the thermal conduction component 21d and VC liquid-cooled heat spreader 21c can promptly conduct the heat generated by the heating surface 11 to the heat dissipation component 22, which dissipates the heat, further enhancing the cooling effect of the ring-shaped thermoelectric cooling chip 1c. Placing the magnet 3c on the inner or outer ring of the ring-shaped thermoelectric cooling chip 1c enables magnetic adsorption of the mobile terminal, improving the convenience of charging.

As shown in FIG. 13, the magnetic wireless charger with cooling functionality includes a housing, typically comprising a front housing 1001 and a rear housing (not shown). Usually, the front housing 1001 and rear housing are tightly connected via snaps, screws, or welding. Both the front housing 1001 and rear housing can be made of plastic or metal.

### Embodiment 5

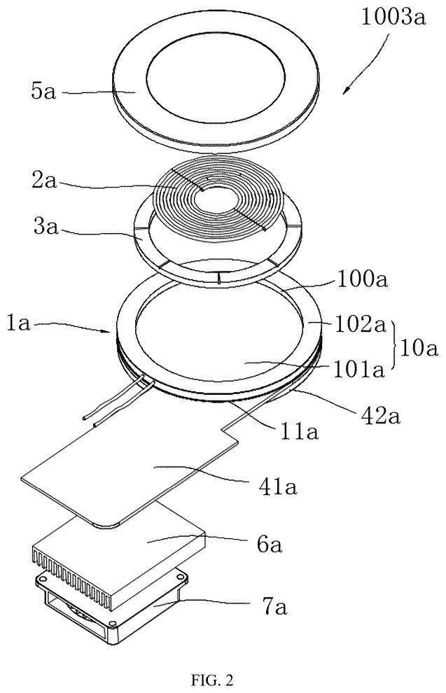

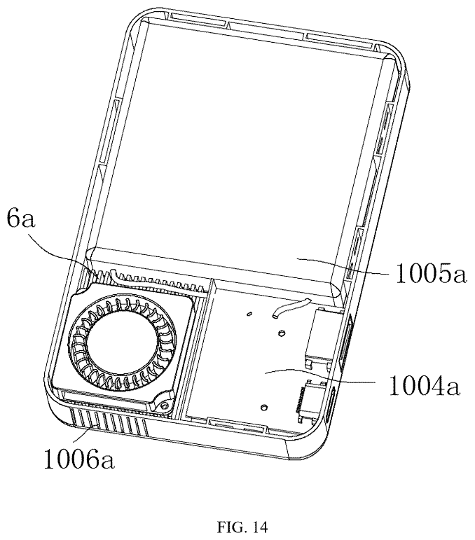

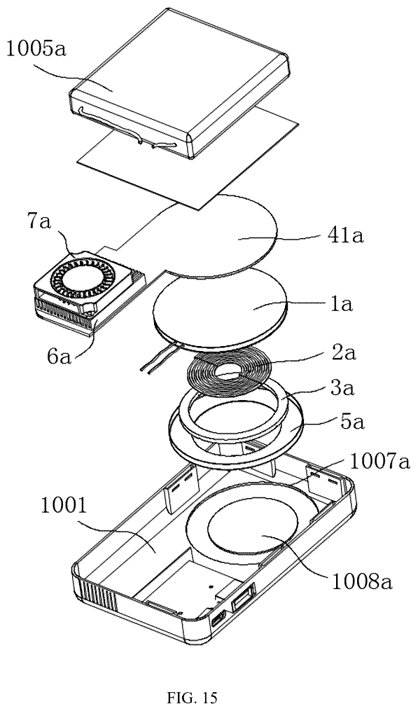

As shown in FIGS. 14, 15, and 2, a through hole 1007a is opened on the front housing 1001 for installing the thermoelectric cooling chip.

Inside the front housing 1001, the magnetic thermoelectric cooling assembly 1003a, control module, and battery 1005a from Embodiment 1 are installed.

The thermoelectric cooling assembly 1003a includes a heat dissipation component 6a. The control assembly includes a printed circuit board (PCB) board 1004a, which is arranged side by side with the heat dissipation component 6a at the bottom of the front housing 1001. The battery 1005a is located above the PCB board 1004a and the heat dissipation component 6a.

Typically, the cavity top cooling surface 102a is made of ceramic material and can directly contact the mobile terminal to cool it. The direct contact between the cavity top cooling surface 102a and the mobile terminal can be divided into two scenarios. First, the cavity top cooling surface 102a is flush with the top surface of the through hole 1007a, i.e., level with the front surface of the front housing 1001. Second, the cavity top cooling surface 102a is slightly higher, usually within 1 mm, than the top surface of the through hole 1007a, to prevent minor deformation of the front housing 1001 from affecting reliable contact between the mobile terminal and the cavity top cooling surface 102a. Of course, decorative components can also be added to the cavity top cooling surface 102a. The above describes the structure where the cooling surface protrudes from the housing.

Another scenario involves the cooling surface contacting the housing to transfer cold energy. This contact includes direct and indirect contact. Direct contact means the cavity top cooling surface 102a directly presses against the front housing 1001, such as installing the thermoelectric cooling chip in a countersunk hole on the front housing 1001. In this case, the front housing 1001 is usually made of metal with good thermal conductivity to transfer cold energy to the mobile terminal. Indirect contact involves placing a highly conductive material, such as thermal grease, between the cavity top cooling surface 102a and the front housing 1001 to increase contact area and improve thermal conduction.

The above configurations also apply to subsequent embodiments.

The top surface of the cold conduction component 5a can be flush with the front surface of the front housing 1001, or it can be slightly higher than the front surface of the front housing 1001.

In the above structure, the thermoelectric cooling chip 1a is installed within the through hole 1008a, allowing the cavity top cooling surface 102a to be flush with or protrude from the outer surface of the through hole 1008a. The outer surface of the through hole 1008a is the outer surface of the front housing 1001, enabling the cavity top cooling surface 102a to directly contact the mobile terminal. Alternatively, the cavity top cooling surface 102a may also be located inside the through hole 1008a, with the addition of a cold conduction component 5a, which can shield the magnet and coil. The outer surface of the cold conduction component 5a is flush with or protrudes from the outer surface of the through hole 1008a, allowing the cold conduction component 5a to also directly contact the mobile terminal. In both cases, the conduction of cooling energy is direct, with minimal loss, resulting in effective cooling performance. The magnet 3a and coil 2a are embedded within the thermoelectric cooling chip 1a, posing no obstruction to the contact between the cavity top cooling surface 102a and the mobile terminal. The heat generated by the heating surface 11a is first transferred out via the thermal conduction component 41a and then dissipated by the heat dissipation component 6a. Since the heat dissipation component 6a and the thermoelectric cooling chip 1a are not stacked in the thickness direction, the overall thickness can be effectively reduced, enabling the charger to be made very thin for easy portability.

When the front housing 1001 is made of a material with good thermal or cold conductivity, especially metal, the mounting hole 1010 for installing the thermoelectric cooling chip 1a does not need to penetrate the front housing 1001. As shown in FIG. 22, the mounting hole 1010 can be designed as a blind hole. The cooling energy generated by the cooling surface 10a can be transferred to the mobile terminal through the front housing 1001, with minimal cooling loss, ensuring effective cooling performance for the mobile terminal. This approach is also applicable to the embodiments described later.

### Embodiment 6

The structure of a magnetic wireless charger with cooling functionality is largely similar to that of Embodiment Five, with the difference being that the magnetic thermoelectric cooling assembly adopts the structure of the magnetic thermoelectric cooling assembly 1003c from Embodiment Three or Embodiment Four.

### Embodiment 7

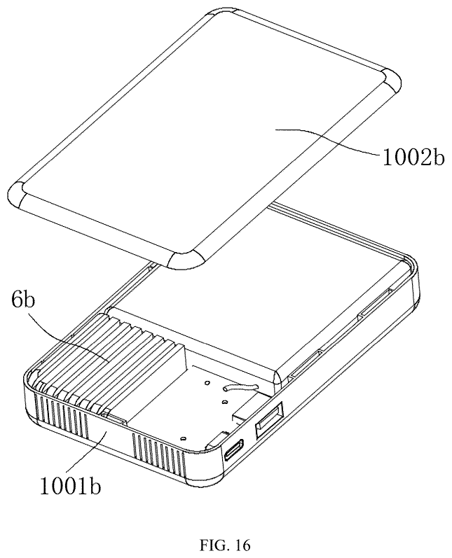

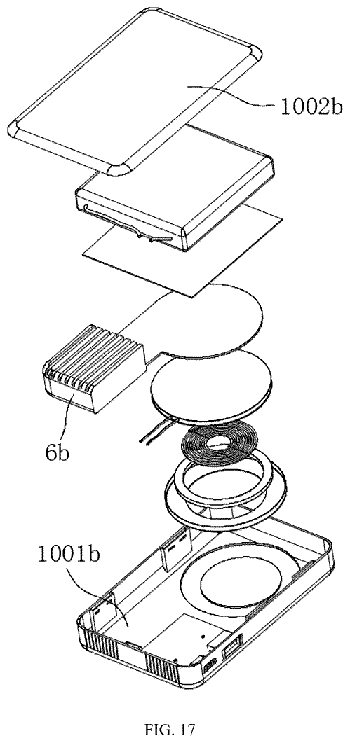

As shown in FIGS. 16 and 17, the structure of this embodiment is largely consistent with that of Embodiment 5, with the difference being that the heat dissipation component is the heat sink block 6b from Embodiment 2. The heat sink block 6b is in contact with the front housing 1001b. In this embodiment, the front housing 1001b is made of aluminum alloy, allowing the heat from the heat sink block 6e to dissipate through the aluminum alloy front housing 1001b. The heat sink block 6b can also contact the rear housing 1002b, which is similarly made of aluminum alloy, further increasing the heat dissipation area.

### Embodiment 8

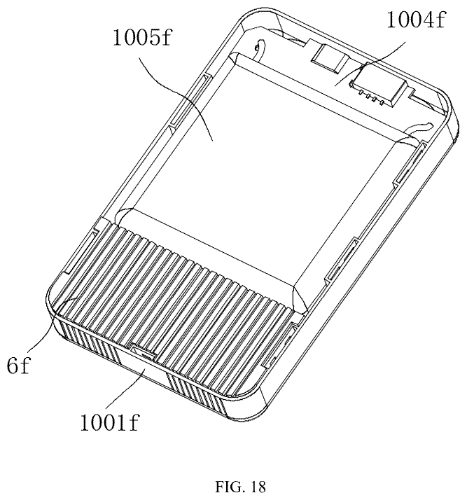

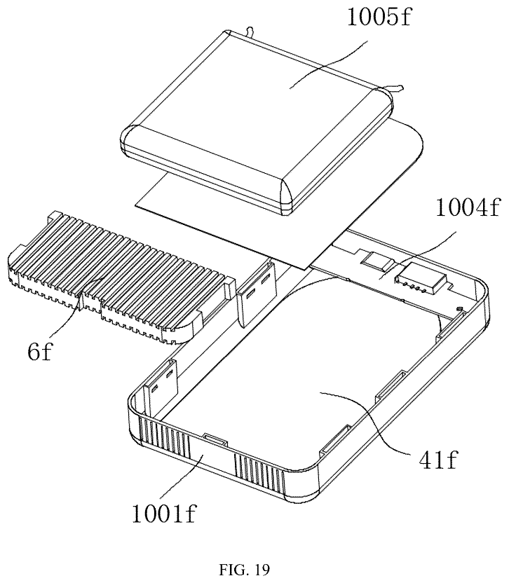

As shown in FIGS. 18 and 19, this embodiment presents another structure without a cooling fan. Here, the width of the thermal conduction component 41f is increased to expand the heat conduction area, and the heat sink block 6f is positioned at the bottom of the front housing 1001f, in contact with it. The front housing 1001f is made of aluminum alloy, enabling the heat from the heat sink block 6f to dissipate through the front housing 1001f. The PCB board 1004f is placed at the top of the front housing 1001f, while the battery 1005f is positioned between the heat sink block 6f and the PCB board 1004f.

Grooves can also be made on the surface of the heat sink block 6f to increase the heat dissipation area. This method eliminates the need for a cooling fan for the heat sink block 6f, reducing production costs. It is also suitable for scenarios with lower cooling power and minimal heat generation.

### Embodiment 9

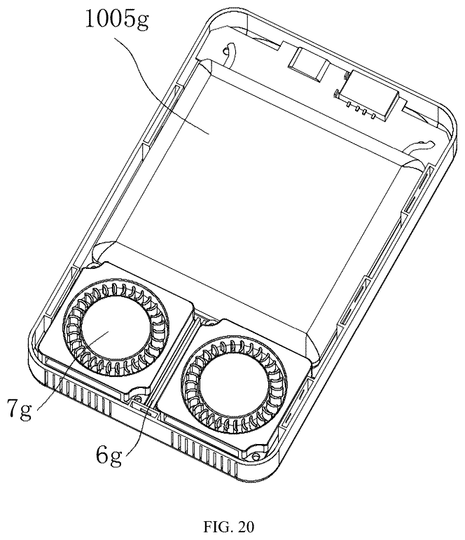

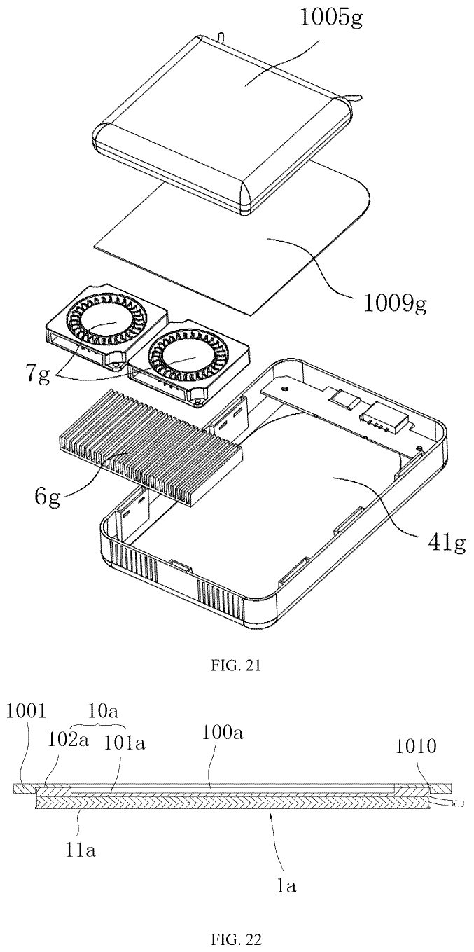

As shown in FIGS. 20 and 21, this embodiment differs from Embodiment 8 in that the heat dissipation component is a heat dissipation fin array 6g, supplemented with a cooling fan 7g. Here, the number of cooling fans 7g is two, and heat dissipation holes corresponding to the air outlets of the cooling fans 7g are provided at the bottom of the front housing 1001g.

A thermal insulation block 1009g is placed between the thermal conduction component 41g and the battery 1005g to prevent the battery from overheating.

This solution is suitable for scenarios with high cooling power and significant heat generation. The cooling fan 7g can quickly expel heat transferred to the heat dissipation fin array 6g from the housing, ensuring excellent heat dissipation.

In the embodiments described above, an insulating block is provided between the thermal conduction component and the battery to protect the battery and prevent overheating.

In the above embodiments, the cooling surface can directly contact the mobile terminal, enabling direct and low-loss conduction of cooling capacity, resulting in effective cooling performance. The magnetic component and coil are embedded in the thermoelectric cooling chip, posing no obstruction to the contact between the cooling surface and the mobile terminal. The heat generated by the heating surface is first conducted through the thermal conduction component to the heat dissipation component, which then dissipates it. Since the heat dissipation component and the thermoelectric cooling chip are not stacked in the thickness direction, the thickness can be effectively reduced, allowing the charger to be made very thin for easy portability. This solution is not only suitable for chargers but can also be adapted for portable power banks.

What is claimed is:

1. A magnetic thermoelectric cooling assembly, comprising a thermoelectric cooling chip, wherein
the thermoelectric cooling chip comprises a cooling surface and a heating surface;
the thermoelectric cooling chip has a concave cavity extending from a side of the cooling surface toward a side of the heating surface, with the cooling surface forming a cavity base cooling surface and a cavity top cooling surface with a height difference; and
on the side of the heating surface, a heat dissipation device is provided, and the heat dissipation device comprises a thermal conduction component of a certain length, with one end of the thermal conduction component contacting the heating surface for heat transfer; the other end of the heat dissipation device is equipped with a heat dissipation component to increase a heat dissipation area or a heat storage capacity; and a magnetic component is arranged within the concave cavity.

2. The magnetic thermoelectric cooling assembly according to claim 1, wherein the heat dissipation device further comprises a heat storage unit, with one end of the thermal conduction component embedded within the heat storage unit; and the magnetic component is a magnet, and on a side of the cooling surface of the thermoelectric cooling chip, a cold conduction component is provided to simultaneously cover both the thermoelectric cooling chip and the magnet.

3. The magnetic thermoelectric cooling assembly according to claim 2, wherein the cold conduction component is made of aluminum alloy or silicone; and the thermal conduction component is a copper tube; and the heat storage unit is an aluminum block, with the copper tube embedded within the aluminum block.

4. The magnetic thermoelectric cooling assembly according to claim 1, wherein the thermal conduction component is a Vapor Chamber (VC) liquid-cooled heat spreader, and a shape of an end of the VC liquid-cooled heat spreader in contact with the thermoelectric cooling chip matches a shape of the thermoelectric cooling chip.

5. The magnetic thermoelectric cooling assembly according to claim 1, wherein the heat dissipation component is a heat dissipation fin array or a heat sink block; and
the magnetic thermoelectric cooling assembly further comprises a cooling fan, the cooling fan is configured to dissipate heat from the heat dissipation fin array.

6. The magnetic thermoelectric cooling assembly according to claim 2, wherein thermal conductive grease is applied between the thermoelectric cooling chip and the cold conduction component; and thermal conductive grease is applied between the thermoelectric cooling chip and the thermal conduction component.

7. The magnetic thermoelectric cooling assembly according to claim 1, wherein the cavity top cooling surface has a rectangular shape; and the cavity base cooling surface has a circular cross-section.

8. A magnetic thermoelectric cooling assembly, comprising a ring-shaped thermoelectric cooling chip, wherein the ring-shaped thermoelectric cooling chip comprises a cooling surface and a heating surface, a heat dissipation device is provided on a side of the heating surface; and the heat dissipation device comprising a thermal conduction component of a certain length, and the thermal conduction component is in contact with the heating surface for heat transfer; and one end of the thermal conduction component forms a ring matching a shape of the ring-shaped thermoelectric cooling chip, and at the other end of the thermal conduction component, a heat dissipation component is provided to increase a heat dissipation area or a heat storage capacity; and
a magnetic component is provided on an inner or outer ring of the ring-shaped thermoelectric cooling chip.

9. The magnetic thermoelectric cooling assembly according to claim 8, wherein the heat dissipation device further comprises a heat storage unit, an end of the thermal conduction component where the ring is arranged is embedded within the heat storage unit; and
the magnetic component is a magnet, and a side of the cooling surface of the ring-shaped thermoelectric cooling chip is provided with a cold conduction component capable of covering both the ring-shaped thermoelectric cooling chip and the magnet.

10. The magnetic thermoelectric cooling assembly according to claim 9, wherein a top surface of the thermal conduction component is lower than a top surface of the heat storage unit; and
the thermal conduction component is a copper tube, a middle portion of the copper tube is bent to form a ring matching a shape of the ring-shaped thermoelectric cooling chip; and two ends of the copper tube extend parallelly away from the ring.

11. The magnetic thermoelectric cooling assembly according to claim 8, wherein the thermal conduction component is a VC liquid-cooled heat spreader, and an end of the VC liquid-cooled heat spreader in contact with the ring-shaped thermoelectric cooling chip forms a ring matching the shape of the ring-shaped thermoelectric cooling chip.

12. The magnetic thermoelectric cooling assembly according to claim 9, wherein the heat storage unit is ring-shaped, and an outer diameter of the heat storage unit being greater than that of the thermal conduction component; and an inner diameter of the heat storage unit is less than or equal to the outer diameter of the thermal conduction component.

13. The magnetic thermoelectric cooling assembly according to claim 9, wherein the heat storage unit is circular, and an outer diameter of the heat storage unit is larger than that of the thermal conduction component; and an accommodating cavity is formed on the heat storage unit, and the accommodating cavity extends inward from a side in contact with the thermal conduction component.

14. A magnetic wireless charger with cooling functionality, comprising a housing, wherein
a thermoelectric cooling assembly and a control assembly are arranged inside the housing;
the thermoelectric cooling assembly comprises a thermoelectric cooling chip, the thermoelectric cooling chip comprises a cooling surface and a heating surface; the cooling surface protrudes from the housing or contacts the housing to transfer cold through the housing; a heat dissipation device is provided on a side of the heating surface, and the heat dissipation device comprises a thermal conduction component with a certain length, one end of the thermal conduction component contacts the heating surface for heat transfer; at the other end of the thermal conduction component, a heat dissipation component is provided to increase a heat dissipation area or a heat storage capacity; and
the thermoelectric cooling assembly further comprises a magnetic component and a coil, the magnetic component and the coil are embedded in the thermoelectric cooling chip.

15. The magnetic wireless charger with cooling functionality according to claim 14, wherein a heat dissipation hole corresponding to the heat dissipation component is provided at an end of the housing away from the thermoelectric cooling chip; and
a through hole is formed in the housing for installing the thermoelectric cooling chip, with the cooling surface being flush with or protruding from an outer surface of the through hole; and
an upper surface of the magnetic component is flush with the cooling surface or lower than the cooling surface.

16. The magnetic wireless charger with cooling functionality according to claim 14, wherein the thermoelectric cooling chip has a concave cavity extending from a side of the cooling surface to a side of the heating surface, forming a cavity base cooling surface and a cavity top cooling surface with a height difference, and the magnetic component and the coil are embedded in the concave cavity.

17. The magnetic wireless charger with cooling functionality according to claim 14, wherein the thermoelectric cooling chip is annular, and the magnetic component and the coil are embedded in an inner ring of the thermoelectric cooling chip.

18. The magnetic wireless charger with cooling functionality according to claim 14, wherein the control assembly comprises a printed circuit board (PCB) board arranged side by side with the heat dissipation component at the bottom of the housing; and a battery is further provided inside the housing, and the battery is located above the PCB board and the heat dissipation component.

19. The magnetic wireless charger with cooling functionality according to claim 14, wherein the heat dissipation device further comprises a heat storage unit, and one end of the thermal conduction component is embedded within the heat storage unit;
the heat dissipation component is a combination of a heat dissipation fin array and a cooling fan, or the heat dissipation component is a heat sink block; and the heat sink block is in contact with the housing to dissipate heat; and
the thermal conduction component is a copper tube, a VC liquid-cooled heat spreader, or a graphene plate, and the heat storage unit is an aluminum block or a copper block.

20. The magnetic wireless charger with cooling functionality according to claim 14, wherein the thermoelectric cooling assembly further comprises a surface cover that covers the coil, the magnetic component, and the thermoelectric cooling chip, or only covers the magnetic component and the coil.
